(19) United States
(12) Patent Application Publication
(10) Pub. No.: US 2006/0240627 A1
(43) Pub. Date: Oct. 26, 2006

(54) Method for manufacturing semiconductor device capable of improving breakdown voltage characteristics

(75) Inventor: Tomoharu Inoue, Kawasaki (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI (JP)

(21) Appl. No.: 11/406,294

(22) Filed: Apr. 19, 2006

(30) Foreign Application Priority Data
Apr. 20, 2005 (JP) 2005-122864

(51) Int. Cl. H01L 21/336

(52) U.S. Cl. 438/289; 438/291

(57) ABSTRACT

In a method for manufacturing a MOS transistor, a MOS transistor isolation layer is formed within a semiconductor substrate to surround an area for forming the MOS transistor in the semiconductor substrate. Then, first impurities are introduced into the area of the semiconductor substrate to adjust a threshold voltage of the MOS transistor. Also, second impurities are introduced into only a part of a periphery of the above-mentioned area adjacent to the MOS transistor isolation layer above which a gate electrode of the MOS transistor will be formed.

### BACKGROUND OF THE INVENTION

1. Field of the Invention

The present invention relates to a method for manufacturing a semiconductor device such as a metal oxide semiconductor (MOS) transistor partitioned by a thick element isolation layer such as a shallow trench isolation (STI) layer or a local oxidation of silicon (LOCOS) layer.

2. Description of the Related Art

When manufacturing a MOS transistor, impurities are introduced into a silicon substrate under a gate electrode, to thereby adjust the threshold voltage of the MOS transistor. On the other hand, in order to partition MOS transistors from each other, a thick element isolation layer such as an STI layer or a LOCOS layer made of silicon dioxide, has been introduced.

When the width and the length of a channel have been decreased, a so-called narrow channel width effect becomes remarkable. For example, in an n-channel MOS transistor, boron atoms are introduced into a silicon substrate under a gate electrode to adjust the threshold voltage; however, in this case, introduced boron atoms are segregated by the thick element isolation layer due to a heating or annealing process, so that the concentration of boron atoms is made lower at the ends of a channel in the width direction than at the center thereof. This is called a hump phenomenon which would decrease the threshold voltage. Similarly, in a p-channel MOS transistor, arsenic (or phosphorus) atoms are introduced into a silicon substrate under a gate electrode to adjust the threshold voltage; however, in this case, introduced arsenic (or phosphorus) atoms are segregated by the thick element isolation layer due to a heating or annealing process, so that the concentration of arsenic (or phosphorus) atoms are made higher at the ends of a channel in the width direction than at the center thereof. This is called a reverse-hump phenomenon which would increase the absolute value of the threshold voltage.

In a prior art method for manufacturing a semiconductor device, in order to compensate for the hump or reverse-hump phenomenon, p-type impurities such as boron atoms are introduced into the entire periphery of the active area adjacent to the element isolation layer, so that the concentration of boron atoms or arsenic (or phosphorus) atoms for adjusting the threshold voltage is substantially made uniform at the ends of a channel and at the center thereof, after a heating or annealing process is carried out. Thus, the threshold voltage would not be changed (see: JP-2000-340791-A & U.S. Pat. No. 6,492,220). This will be explained later in detail.

### SUMMARY OF THE INVENTION

In the above-described prior art manufacturing method, however, since the p-type impurities are introduced into the entire periphery of the active area adjacent to the element isolation layer, the breakdown voltage characteristics deteriorate.

According to the present invention, p-type impurities are introduced into a part of the periphery of the active area adjacent to the element isolation layer that is only beneath the gate electrode. As a result, while the improvement of the sub threshold characteristics is maintained, the breakdown voltage characteristics can be improved.

### BRIEF DESCRIPTION OF THE DRAWINGS

The present invention will be more clearly understood from the description set forth below, as compared with the prior art, with reference to the accompanying drawings, wherein:

FIG. 1A is a plan view for explaining a hump phenomenon generated in a semiconductor device;

FIG. 1B is a cross-sectional view taken along the line B-B of FIG. 1A;

FIG. 1C is a graph showing the concentration of boron atoms in a p-type impurity diffusion region of FIG. 1B, after the p-type impurity diffusion region is subjected to a heating or annealing process;

FIG. 2A is a plan view for explaining a reverse-hump phenomenon generated in a semiconductor device;

FIG. 2B is a cross-sectional view taken along the line B-B of FIG. 2A;

FIG. 2C is a graph showing the concentration of arsenic (or phosphorus) atoms in an n-type impurity diffusion region of FIG. 2B, after the n-type impurity diffusion region is subjected to a heating or annealing process;

FIGS. 3A and 3J are cross-sectional views for explaining a prior art method for manufacturing a semiconductor device;

FIG. 4A is a plan view of the n-channel MOS transistor obtained by the method as illustrated in FIGS. 3A through 3J;

FIG. 4B is a cross-sectional view taken along the line B-B of FIG. 4A;

FIG. 4C is a graph showing the concentration of impurity atoms in the p-type impurity diffusion region of FIG. 4B, after the p-type impurity diffusion region is subjected to a heating or annealing process;

FIG. 5A is a graph showing the sub threshold characteristics of the n-channel MOS transistor obtained by the method as illustrated in FIGS. 3A through 3J;

FIG. 5B is a graph showing the breakdown voltage characteristics of the n-channel MOS transistor obtained by the method as illustrated in FIGS. 3A through 3J;

FIGS. 6A and 6J are cross-sectional views for explaining a first embodiment of the method for manufacturing a semiconductor device according to the present invention;

FIG. 7 is a plan view of the photoresist pattern layer of FIG. 6F;

FIG. 8A is a plan view of the n-channel MOS transistor obtained by the method as illustrated in FIGS. 6A through 6J;

FIG. 8B is a cross-sectional view taken along the line B-B of FIG. 8A;

FIG. 8C is a graph showing the concentration of impurity atoms in the p-type impurity diffusion region of FIG. 8B, after the p-type impurity diffusion region is subjected to a heating or annealing process;

FIG. 9A is a graph showing the sub threshold characteristics of the n-channel MOS transistor obtained by the method as illustrated in FIGS. 6A through 6J;

FIG. 9B is a graph showing the breakdown voltage characteristics of the n-channel MOS transistor obtained by the method as illustrated in FIGS. 6A through 6J; and

FIGS. 10A and 10U are cross-sectional views for explaining a second embodiment of the method for manufacturing a semiconductor device according to the present invention.

### DESCRIPTION OF THE PREFERRED EMBODIMENTS

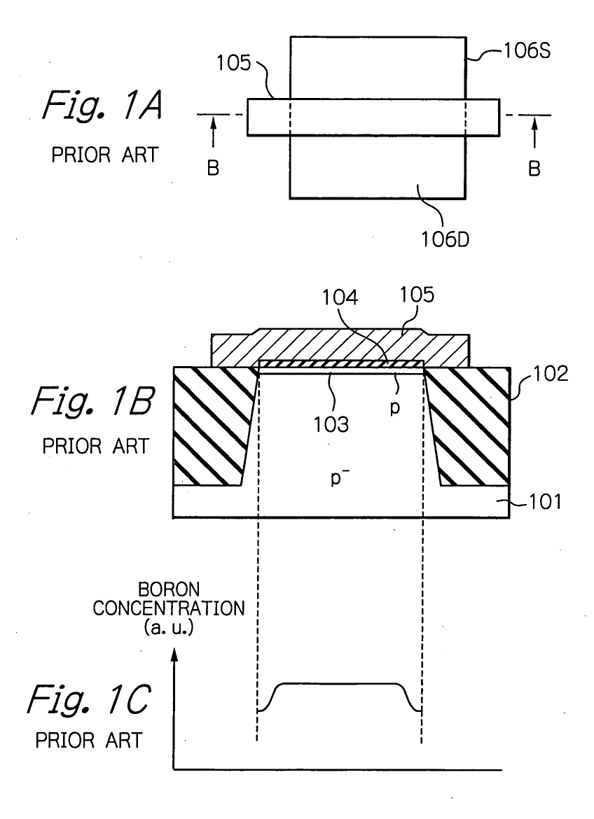

Before the description of the preferred embodiments, a prior art method for manufacturing a semiconductor device will be explained with reference to FIGS. 1A, 1B, 1C, 2A, 2B, 2C, 3A through 3J, 4A, 4B, 4C, 5A and 5B.

First, a hump phenomenon is explained with reference to FIGS. 1A, 1B and 1C. Note that FIG. 1A is a plan view of an n-channel MOS transistor, FIG. 1B is a cross-sectional view taken along the line B-B of FIG. 1A, and FIG. 1C is a graph showing the concentration of boron atoms in a p-type impurity region of FIG. 1B for adjusting a threshold voltage Vₜₕₙ, after the p-type impurity region is subjected to a heating or annealing process.

In FIGS. 1A and 1B, reference numeral 101 designates a p⁻-type monocrystalline silicon substrate surrounded by an element isolation layer 102 which is in this case an STI layer made of silicon dioxide to define a field area. Also, a p-type impurity diffusion region 103 is formed within the silicon substrate 101 in an active area to adjust the threshold voltage Vₜₕₙ. In this case, the p-type impurity diffusion region 103 is operated to increase the threshold voltage Vₜₕₙ. Further, a gate silicon dioxide layer 104 and a gate electrode 105 are formed on the active area. Additionally, n⁺-type impurity diffusion regions 106S and 106D serving as a source region and a drain region, respectively, are formed within the silicon substrate 101 in the active area in self-alignment with the gate electrode 105.

Solid solubility of boron atoms is larger in silicon dioxide than in silicon. Therefore, as shown in FIG. 1C, boron atoms are moved by the above-mentioned heating or annealing process from the silicon substrate 101 to the STI layer 102. As a result, boron atoms are segregated by the STI layer 102, so that the concentration of boron atoms is made lower at the ends of a channel in the width direction than at the center thereof. This is called a hump phenomenon which would decrease the threshold voltage Vₜₕₙ, particularly in a short channel type MOS transistor.

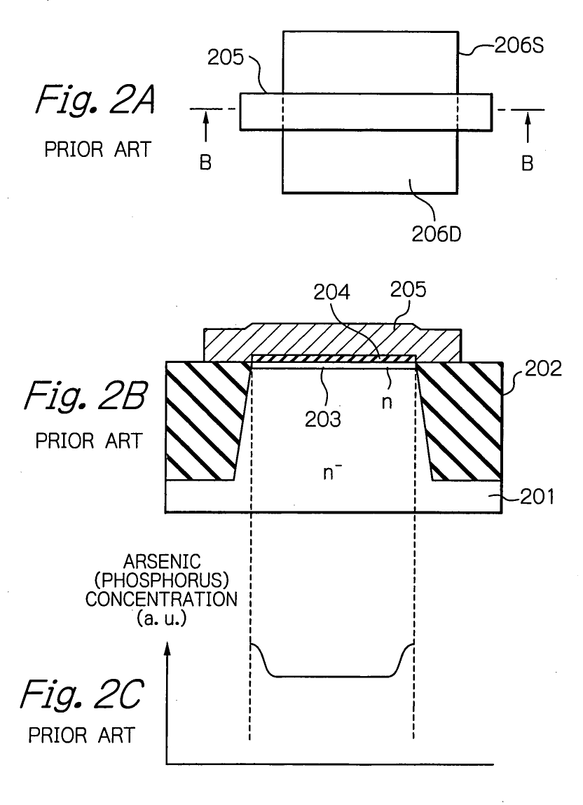

Next, a reverse-hump phenomenon is explained with reference to FIGS. 2A, 2B and 2C. Note that FIG. 2A is a plan view of a p-channel MOS transistor, FIG. 2B is a cross-sectional view taken along the line B-B of FIG. 2A, and FIG. 2C is a graph showing the concentration of arsenic (phosphorus) atoms in an n-type impurity region of FIG. 2B for adjusting a threshold voltage Vₜₕₚ, after the n-type impurity region is subjected to a heating or annealing process.

In FIGS. 2A and 2B, reference numeral 201 designates an n⁻-type monocrystalline silicon substrate surrounded by an element isolation layer 202 which is in this case an STI layer made of silicon dioxide to define a field area. Also, an n-type impurity diffusion region 203 is formed within the silicon substrate 201 in an active area to adjust the threshold voltage Vₜₕₚ. In this case, the n-type impurity diffusion region 203 is operated to increase the absolute value of the threshold voltage Vₜₕₚ. Further, a gate silicon dioxide layer 204 and a gate electrode 205 are formed on the active area. Additionally, p⁺-type impurity diffusion regions 206S and 206D serving as a source region and a drain region, respectively, are formed within the silicon substrate 201 in the active area in self-alignment with the gate electrode 205.

Solid solubility of arsenic (or phosphorus) atoms is smaller in silicon dioxide than in silicon. Therefore, as shown in FIG. 2C, arsenic (or phosphorus) atoms are moved by the above-mentioned heating or annealing process from the STI substrate 202 to the silicon substrate 201. As a result, arsenic (or phosphorus) atoms are segregated by the silicon substrate 201, so that the concentration of arsenic (or phosphorus) atoms is made higher at the ends of a channel in the width direction than at the center thereof. This is called a reverse-hump phenomenon which would increase the absolute value of the threshold voltage Vₜₕₚ, particularly in a short channel type MOS transistor.

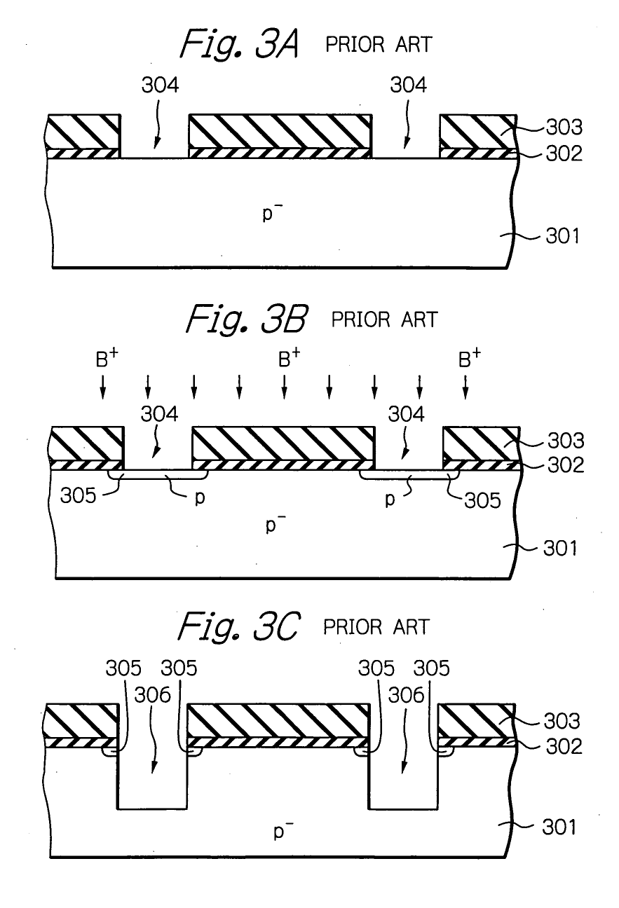

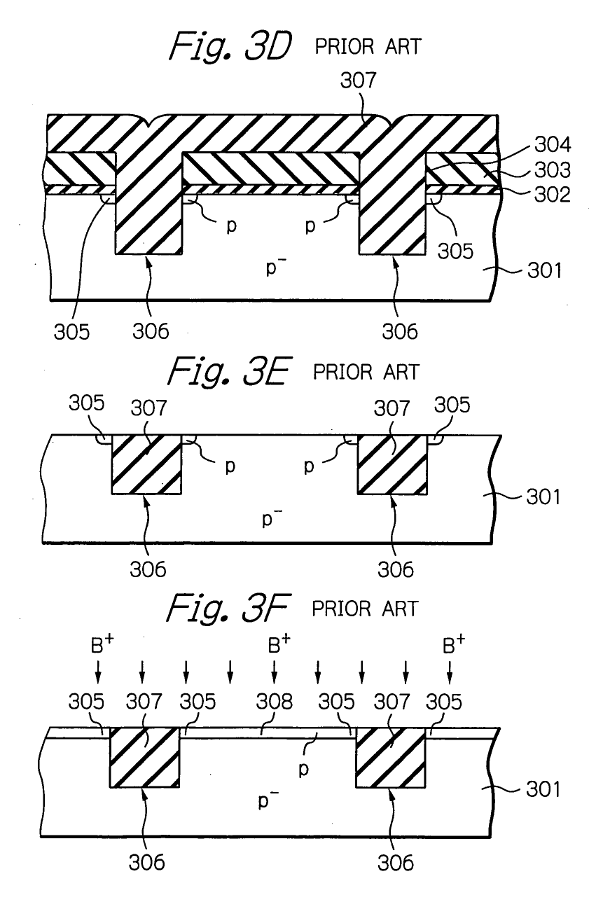

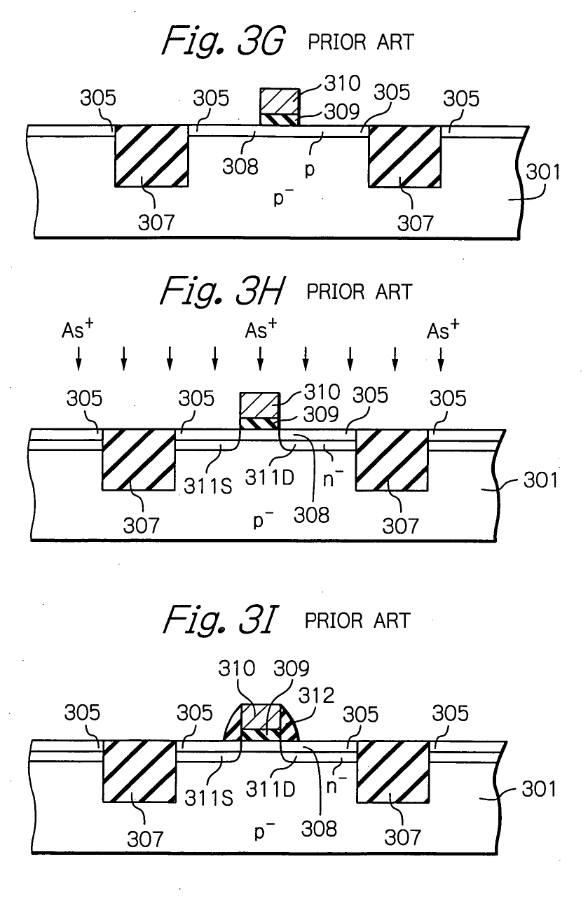

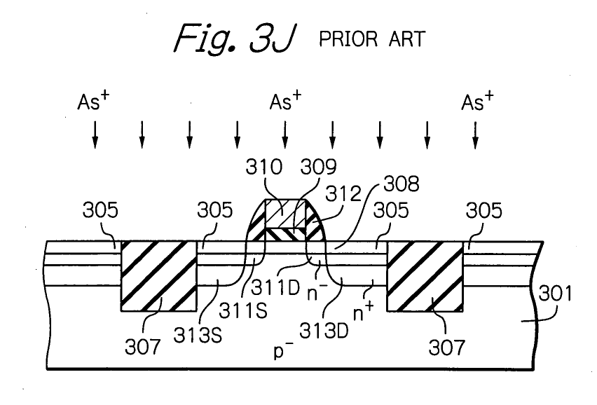

In order to compensate for the above-mentioned hump phenomenon, a prior art method for manufacturing a semiconductor device such as an n-channel MOS transistor will be explained next with reference to FIGS. 3A through 3J (see: JP-2000-340791-A & U.S. Pat. No. 6,492,220).

First, referring to FIG. 3A, a silicon dioxide layer 302 and a silicon nitride layer 303 are deposited on a p⁻-type monocrystalline silicon substrate 301. In this case, the silicon dioxide layer 302 can be formed by thermally oxidizing the silicon substrate 301. Then, an opening 304 is perforated in the silicon nitride layer 303 and the silicon dioxide layer 302 by a photolithography and etching process.

Next, referring to FIG. 3B, boron ions are implanted into the silicon substrate 301 by using the silicon nitride layer 303 and the silicon dioxide layer 302 as a mask. As a result, a p-type impurity diffusion region 305 is formed at the bottom of the opening 304 and beneath the silicon dioxide layer 302. That is, since boron ions have a large diffusion coefficient for the silicon substrate 301, boron ions are easily diffused into the silicon substrate 301 along the horizontal and vertical directions.

Next, referring to FIG. 3C, the silicon substrate 301 is etched by using the silicon nitride layer 303 and the silicon dioxide layer 302 as a mask. As a result, a trench (groove) 306 is formed within the silicon substrate 301.

Next, referring to FIG. 3D, a silicon dioxide layer 307 is buried in the trench 306 of the silicon substrate 301 and the opening 304 of the silicon nitride layer 303 and the silicon dioxide layer 302 by a thermal oxidation process and a chemical vapor deposition (CVD) process.

Next, referring to FIG. 3E, the silicon dioxide layer 307, the silicon nitride layer 303 and the silicon dioxide layer 302 are flattened by a chemical mechanical polishing (CMP) process. As a result, the silicon dioxide layer 307 is left only within the trench 306. Thus, the silicon dioxide layer 307 buried in the trench 306 serves as an STI layer, to partition element forming areas (active areas) from each other.

Next, referring to FIG. 3F, boron ions are implanted into the silicon substrate 301 to form a p-type impurity diffusion region 308 within the silicon substrate 301. Note that the p-type impurity diffusion region 308 including the p-type impurity diffusion region 305 is used for adjusting the threshold voltage Vₜₕₙ of an n-channel MOS transistor which will be formed.

Next, referring to FIG. 3G, after the surface of the device is cleaned and rinsed, a silicon dioxide layer is formed by thermally oxidizing the silicon substrate 301, and a polycrystalline silicon layer is deposited on the silicon dioxide layer by a CVD process. Then, the polycrystalline silicon layer and the silicon dioxide layer are patterned by a photolithography and etching process, so that a gate silicon dioxide layer 309 and a gate electrode 310 are formed.

Next, referring to FIG. 3H, arsenic ions are implanted into the silicon substrate 301 by using the gate electrode 310 and the gate silicon dioxide layer 309 as a mask. As a result, n⁻-type impurity regions 311S and 311D for a lightly-doped drain (LDD) structure are formed within the silicon substrate 301.

Next, referring to FIG. 31, a silicon dioxide layer is deposited on the entire surface by a CVD process, and the silicon dioxide layer is etched back by an anisotropic etching process. As a result, a sidewall silicon dioxide layer 312 is formed on the sidewalls of the gate silicon dioxide layer 309 and the gate electrode 310.

Finally, referring to FIG. 3J, arsenic ions are again implanted into the silicon substrate 301 by using the gate electrode 310, the gate silicon dioxide layer 309 and the sidewall silicon dioxide layer 312 as a mask. As a result, n⁺-type impurity regions 313S and 313D serving as a source and a drain, respectively, are formed within the silicon substrate 301.

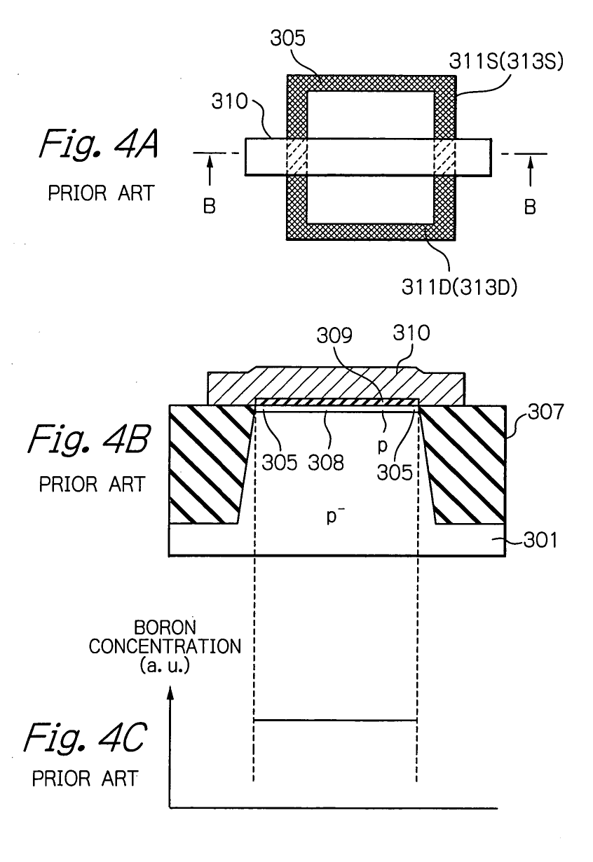

FIG. 4A is a plan view of the n-channel MOS transistor obtained by the method as illustrated in FIGS. 3A through 3J, FIG. 4B is a cross-sectional views taken along the line B-B of FIG. 4A, and FIG. 4C is a graph showing the concentration of boron atoms in the p-type impurity region 308 including the p-type impurity region 305 of FIG. 4B for adjusting the threshold voltage Vₜₕₙ, after the p-type impurity regions 305 and 308 are'subjected to a heating or annealing process.

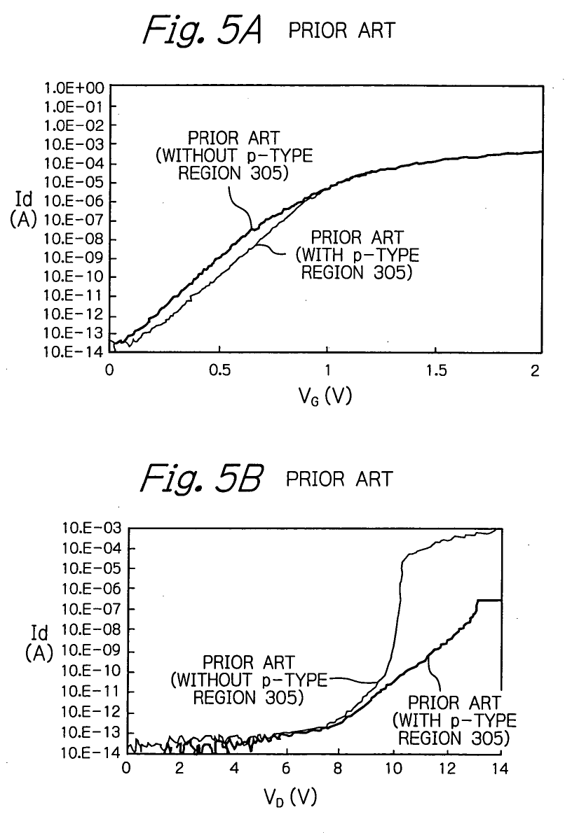

As illustrated in FIGS. 4A and 4B, the p-type impurity diffusion region 305 is provided on the entire periphery of the active area. Therefore, as shown in FIG. 4C, when boron atoms are moved by the above-mentioned heating or annealing process from the silicon substrate 301 to the STI layer 307, due to the presence of the p-type impurity diffusion region 305, the concentration of boron atoms is made uniform at the ends of a channel in the width direction and at the center thereof. Thus, the hump phenomenon can be compensated for, which would not decrease the threshold voltage Vₜₕₙ as shown in FIG. 5A where V_{G} is a gate voltage and I_{d} is a drain current. Note that FIG. 5A is a graph showing the sub threshold characteristics of the n-channel MOS transistor obtained by the method as illustrated in FIGS. 3A through 3J. That is, the sub threshold characteristics of the n-channel MOS transistor obtained by the method as illustrated in FIGS. 3A through 3J where the p-type impurity diffusion region 305 is provided are improved as compared with those of the n-channel MOS transistor where the p-type impurity diffusion region 305 is not provided. Note that the improvement of the sub threshold characteristics is mainly due to the p-type impurity diffusion region 305 located beneath the gate electrode 310, as indicated by dotted, hatched portions in FIG. 4A.

However, as shown in FIG. 5B which is a graph showing the breakdown voltage characteristics of the n-channel MOS transistor obtained by the method as illustrated in FIGS. 3A through 3J where V_{D} is a source-to-drain voltage and I_{D} is a drain current, the breakdown voltage characteristics of the n-channel MOS transistor obtained by the method as illustrated in FIGS. 3A through 3J where the p-type impurity diffusion region 305 is provided deteriorate as compared with those of the n-channel MOS transistor where the p-type impurity diffusion region 305 is not provided. Note that the deterioration of the breakdown voltage characteristics is mainly due to the p-type impurity diffusion region 305 located in the source region 311S (313S) and the drain region 311D (313D), as indicated by solid double-hatched portions in FIG. 4A. Therefore, particularly, when the integration is enhanced to decrease the size of the impurity diffusion regions 311S (313S) and 311D (313D), the breakdown voltage characteristics further deteriorate.

The above-described prior art method is valid for a p-channel MOS transistor where the impurity diffusion regions 308, 311S (313S) and 311D (313D) of FIGS. 3A through 3J is of a p-type. That is, although the reverse-hump phenomenon is compensated for by the p-type impurity diffusion region 305 so that the sub threshold characteristics are improved, the breakdown voltage characteristics deteriorate.

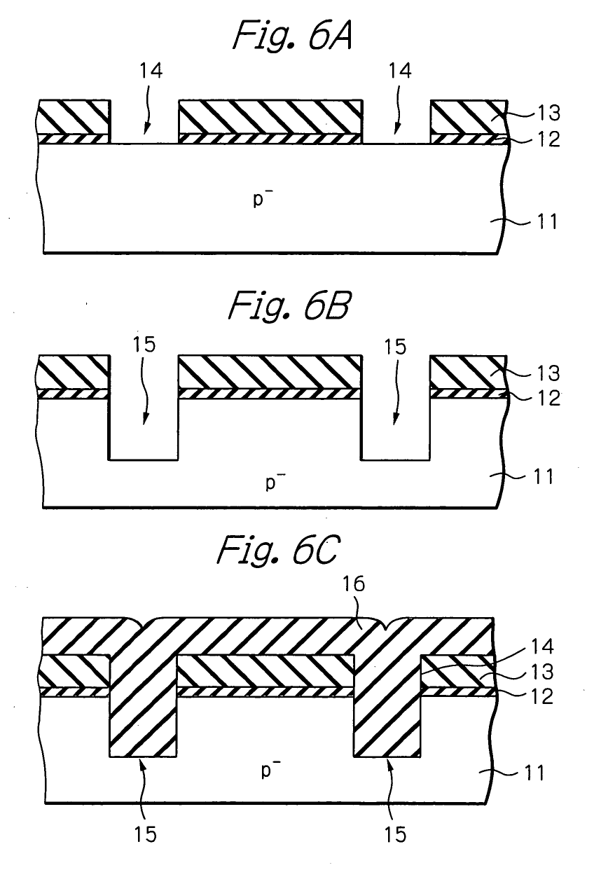

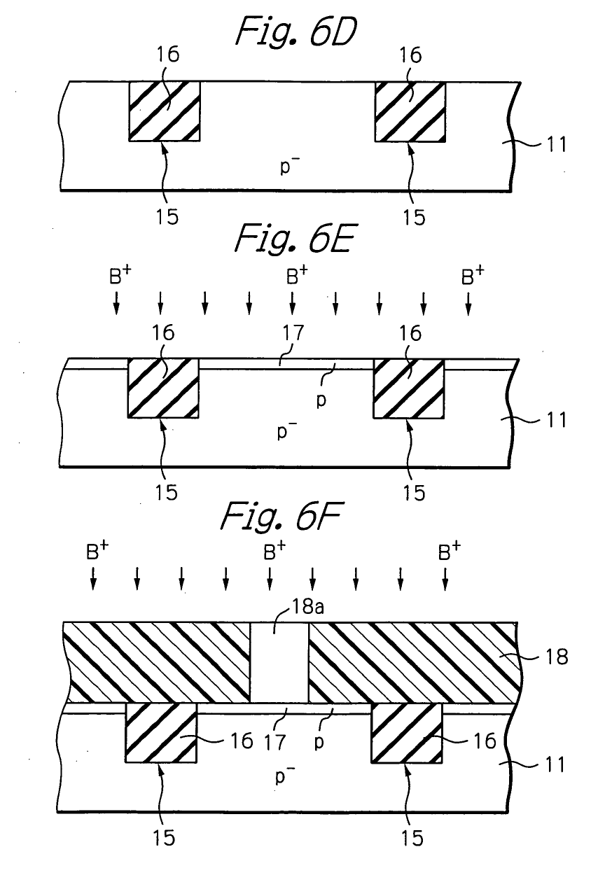

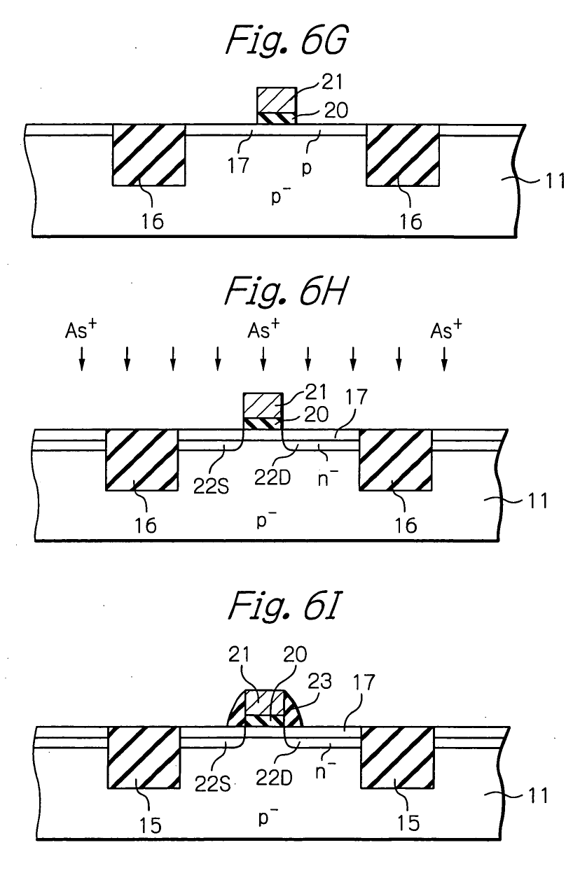

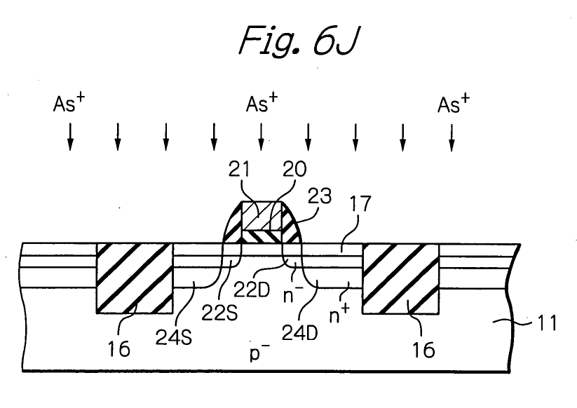

A first embodiment of the method for manufacturing a semiconductor device such as an n-channel MOS transistor will be explained next with reference to FIGS. 6A through 6J.

First, referring to FIG. 6A, a silicon dioxide layer 12 and a silicon nitride layer 13 are deposited on a p⁻-type monocrystalline silicon substrate 11. In this case, the silicon dioxide layer 12 can be formed by thermally oxidizing the silicon substrate 11. Then, an opening 14 is perforated in the silicon nitride layer 13 and the silicon dioxide layer 12 by a photolithography and etching process.

Next, referring to FIG. 6B, the silicon substrate 11 is etched by using the silicon nitride layer 13 and the silicon dioxide layer 12 as a mask. As a result, a trench (groove) 15 is formed within the silicon substrate 11.

Next, referring to FIG. 6C, a silicon dioxide layer 16 is buried in the trench 15 of the silicon substrate 11 and the opening 14 of the silicon nitride layer 13 and the silicon dioxide layer 12 by a thermal oxidation process and a CVD process.

Next, referring to FIG. 6D, the silicon dioxide layer 16, the silicon nitride layer 13 and the silicon dioxide layer 12 are flattened by a CMP process. As a result, the silicon dioxide layer 16 is left only within the trench 15. Thus, the silicon dioxide layer 16 buried in the trench 15 serves as an STI layer, to partition element forming areas (active areas) from each other.

Next, referring to FIG. 6E, boron ions are implanted into the silicon substrate 11 to form a p-type impurity diffusion region 17 within the silicon substrate 11. Note that the p-type impurity diffusion region 17 is used for adjusting the threshold voltage Vₜₕₙ of an n-channel MOS transistor which will be formed.

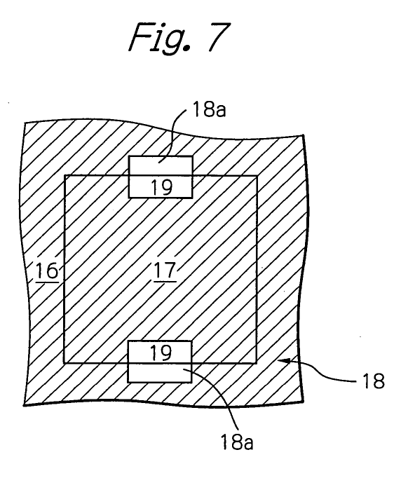

Next, referring to FIG. 6F, a photoresist layer is coated on the entire surface, and the photoresist layer is patterned by a photolithography process to form a photoresist pattern layer 18 having openings 18a corresponding to a part of the periphery of the active area adjacent to the STI layer 16 that is only beneath agate electrode 21 which will be formed later. The photoresist pattern layer 18 is illustrated in FIG. 7. Then, boron ions are implanted into the silicon substrate 11 by using the photoresist pattern layer 18 as a mask. As a result, p-type impurity diffusion regions 19 which are shown not in FIG. 6F but in FIG. 7 are formed at the bottom of the openings 18a and within the p-type impurity diffusion region 17. That is, boron ions have a large diffusion coefficient for the silicon substrate 11, i.e., the p-type impurity diffusion region 17, boron ions are easily diffused into the p-type impurity diffusion region 17 along the horizontal and vertical directions. Then, the photoresist pattern layer 18 is removed by an ashing process or the like.

Note that the size of the openings 18a of FIG. 6F is determined so as to compensate for the hump phenomenon of the p-type impurity diffusion region 17.

Next, referring to FIG. 6G, after the surface of the device is cleaned and rinsed, a silicon dioxide layer is-formed by thermally oxidizing the silicon substrate 11, and a polycrystalline silicon layer is deposited on the silicon dioxide layer by a CVD process. Then, the polycrystalline silicon layer and the silicon dioxide layer are patterned by a photolithography and etching process, so that a gate silicon dioxide layer 20 and a gate electrode 21 are formed.

In FIG. 6G, the gate silicon dioxide layer 20 is formed in self-alignment with the gate electrode 21 immediately after the formation thereof; however, the gate silicon dioxide layer 20 can be formed immediately before silicide layers (not shown) are formed at a post stage.

Next, referring to FIG. 6H, arsenic ions are implanted into the silicon substrate 11 by using the gate electrode 21 and the gate silicon dioxide layer 20 as a mask. As a result, n⁻-type impurity regions 22S and 22D for an LDD structure are formed within the silicon substrate 11.

Next, referring to FIG. 6I, a silicon dioxide layer is deposited on the entire surface by a CVD process, and the silicon dioxide layer is etched back by an anisotropic etching process. As a result, a sidewall silicon dioxide layer 23 is formed on the sidewalls of the gate silicon dioxide layer 20 and the gate electrode 21.

Finally, referring to FIG. 6J, arsenic ions are again implanted into the silicon substrate 11 by using the gate electrode 21, the gate silicon dioxide layer 20 and the sidewall silicon dioxide layer 23 as a mask. As a result, n⁺-type impurity regions 24S and 24D serving as a source and a drain, respectively, are formed within the silicon substrate 11.

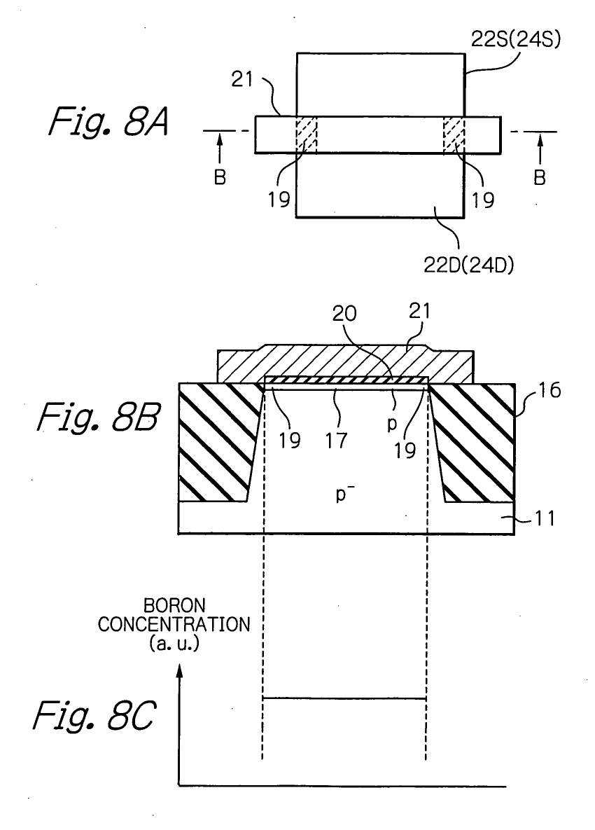

FIG. 8A is a plan view of the n-channel MOS transistor obtained by the method as illustrated in FIGS. 6A through 6J, FIG. 8B is a cross-sectional views taken along the line B-B of FIG. 8A, and FIG. 8C is a graph showing the concentration of boron atoms in the p-type impurity region 17 including the p-type impurity region 19 of FIG. 8B for adjusting the threshold voltage Vₜₕₙ, after the p-type impurity regions 17 and 19 are subjected to a heating or annealing process.

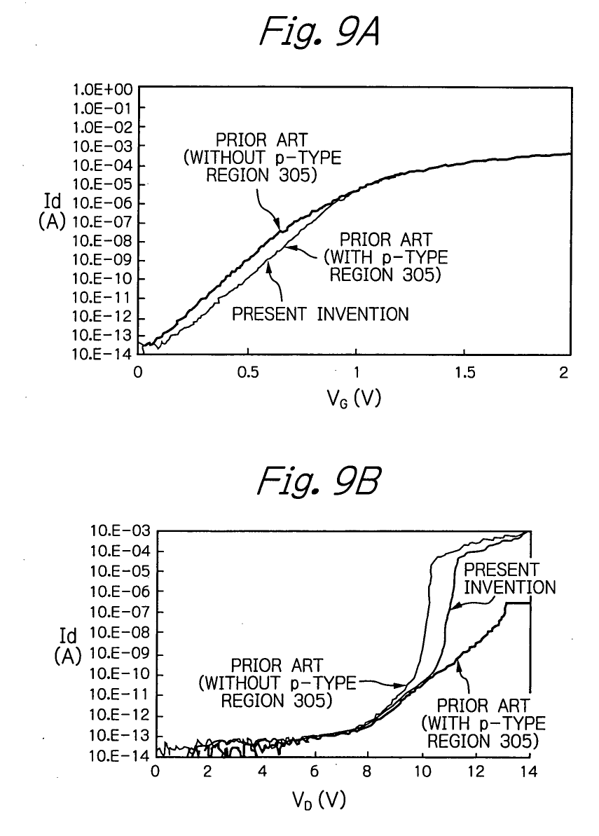

As illustrated in FIGS. 8A and 8B, the p-type impurity diffusion region 19 is provided on the part of the periphery of the active area. Therefore, as shown in FIG. 8C, when boron atoms are moved by the above-mentioned heating or annealing process from the silicon substrate 11 to the STI layer 16, due to the presence of the p-type impurity diffusion region 19, the concentration of boron atoms is made uniform at the ends of a channel in the width direction and at the center thereof. Thus, the hump phenomenon can be compensated for, which would not decrease the threshold voltage Vₜₕₙ as shown in FIG. 9A where V_{G} is a gate voltage and I_{d} is a drain current. Note that FIG. 9A is a graph showing the sub threshold characteristics of the n-channel MOS transistor obtained by the method as illustrated in FIGS. 6A through 6J. That is, the sub threshold characteristics of the n-channel MOS transistor obtained by the method as illustrated in FIGS. 6A through 6J where the p-type impurity diffusion region 19 is provided are improved in the same way as those of the n-channel MOS transistor where the p-type impurity diffusion region 305 is provided. Note that the improvement of the sub threshold characteristics is mainly due to the p-type impurity diffusion region 19 located beneath the gate electrode 21, as indicated by dotted, hatched portions in FIG. 8A.

Simultaneously, as shown in FIG. 9B which is a graph showing the breakdown voltage characteristics of the n-channel MOS transistor obtained by the method as illustrated in FIGS. 6A through 6J where V_{D} is a source-to-drain voltage and I_{D} is a drain current, the breakdown voltage characteristics of the n-channel MOS transistor obtained by the method as illustrated in FIGS. 6A through 6J where the p-type impurity diffusion region 19 is provided hardly deteriorate as compared with those of the n-channel MOS transistor where none of the p-type impurity diffusion region 17 and 19 are provided. That is, the p-type impurity diffusion region 19 is not located in the periphery of the source region 22S (24S) and the drain region 22D (24D). Therefore, particularly, even when the integration is enhanced to decrease the size of the impurity diffusion regions 22S (24S) and 22D (24D), the breakdown voltage characteristics hardly deteriorate.

The above-described first embodiment is valid for a p-channel MOS transistor where the impurity diffusion regions 17, 22S (24S) and 22D (24D) of FIGS. 6A through 6J is of a p-type. That is, the reverse-hump phenomenon is also compensated for by the p-type impurity diffusion region 19 so that the sub threshold characteristics are improved, and also, the breakdown voltage characteristics hardly deteriorate.

In the above-described first embodiment, the formation of the p-type impurity diffusion region 17 is followed by the formation of the p-type impurity diffusion regions 19; however, the formation of the p-type impurity diffusion regions 19 can be followed by the formation of the p-type impurity diffusion region 17.

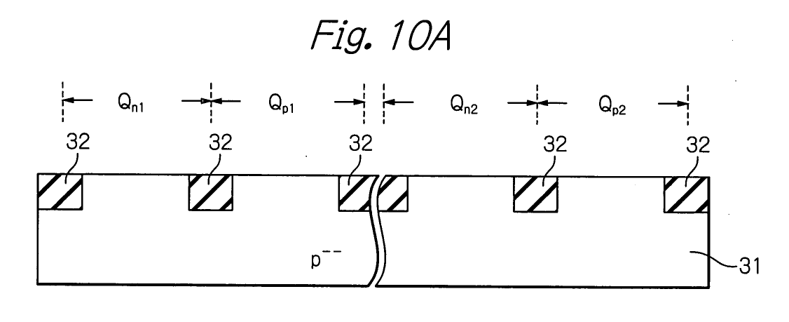

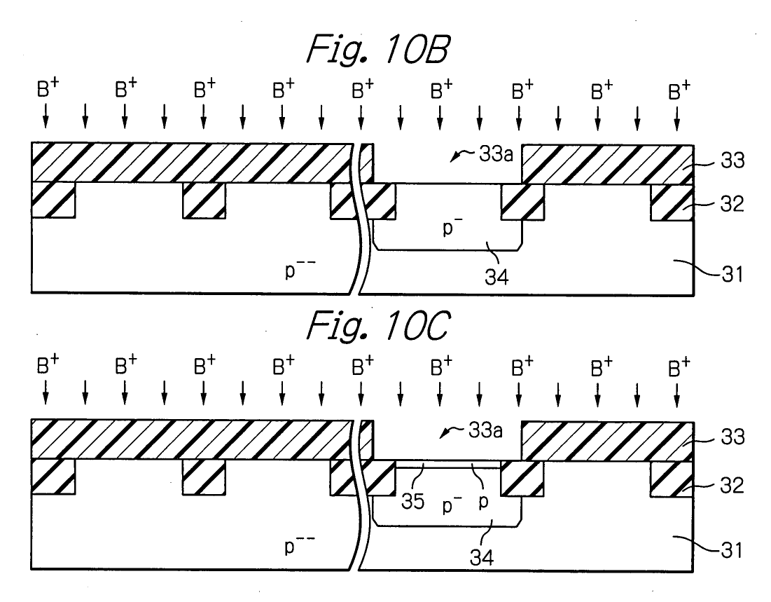

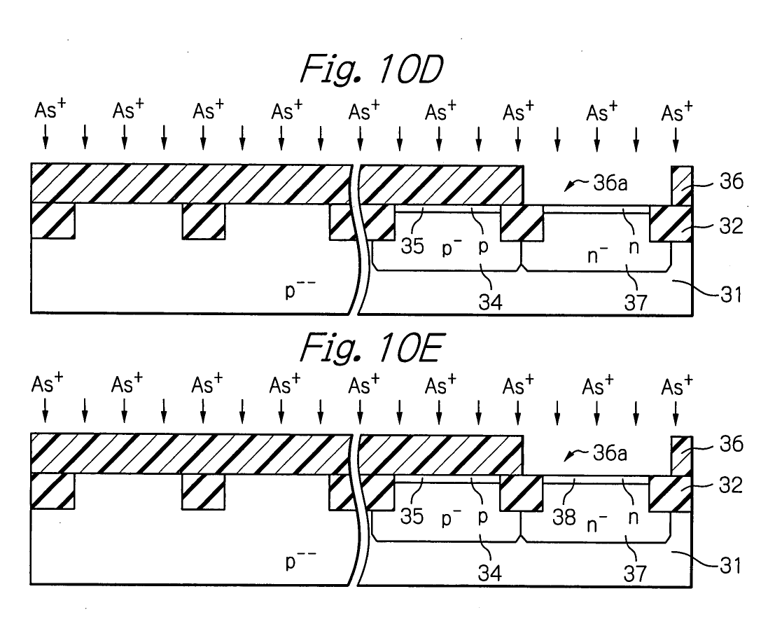

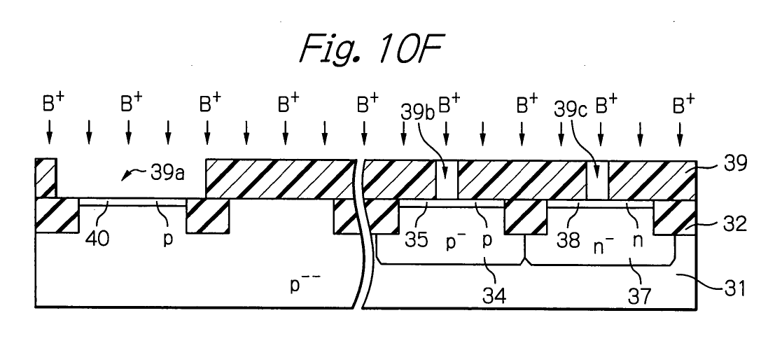

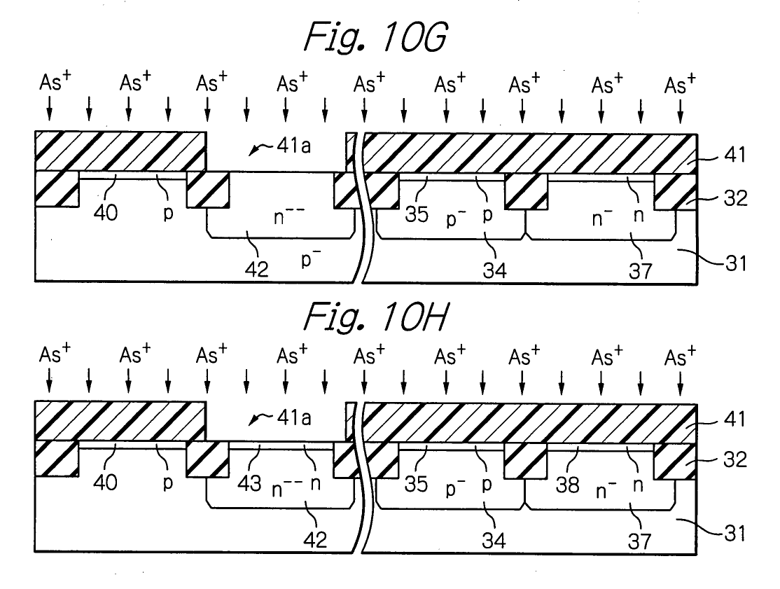

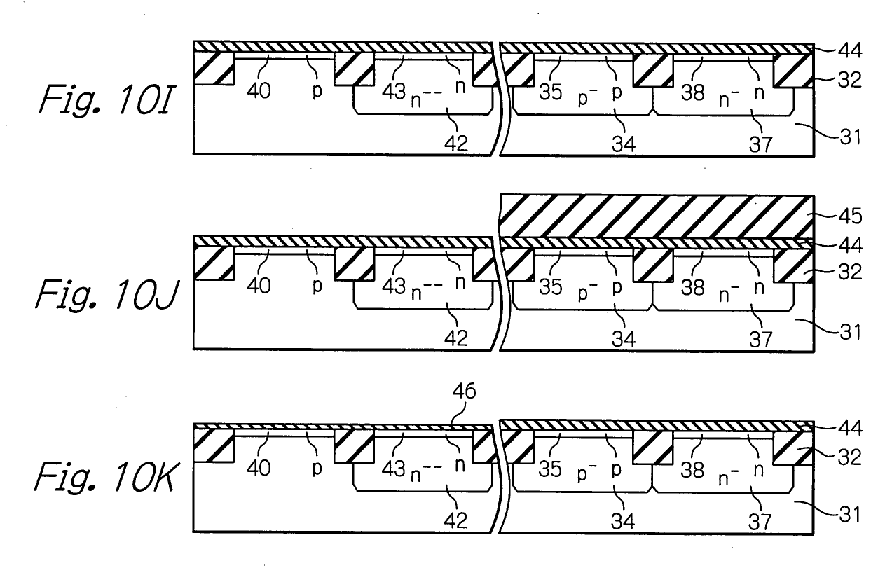

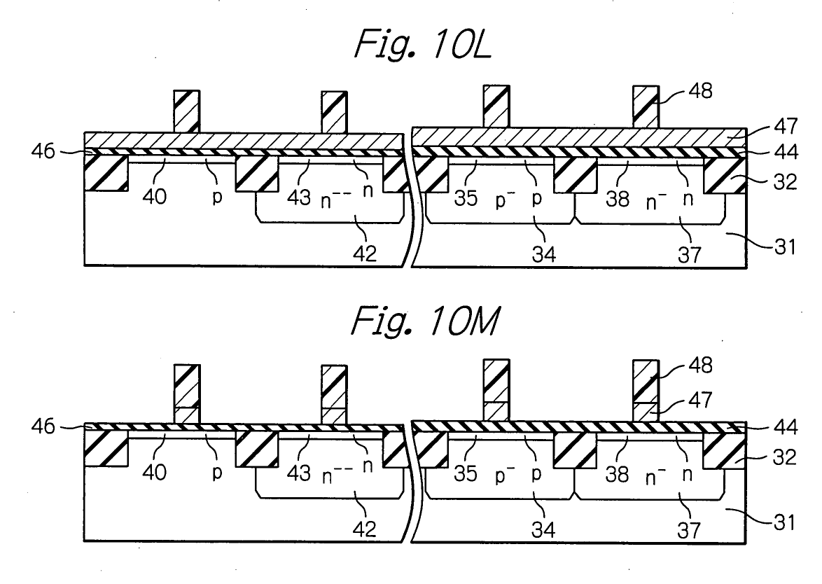

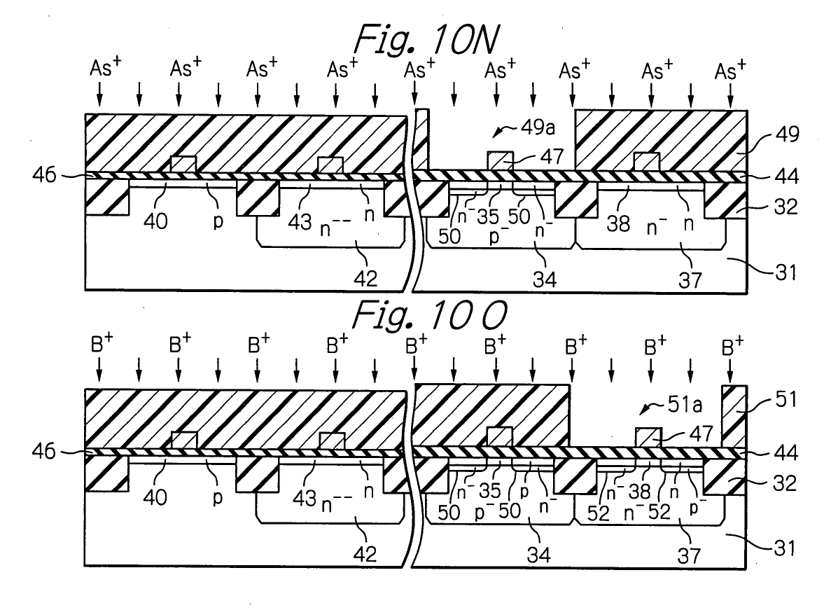

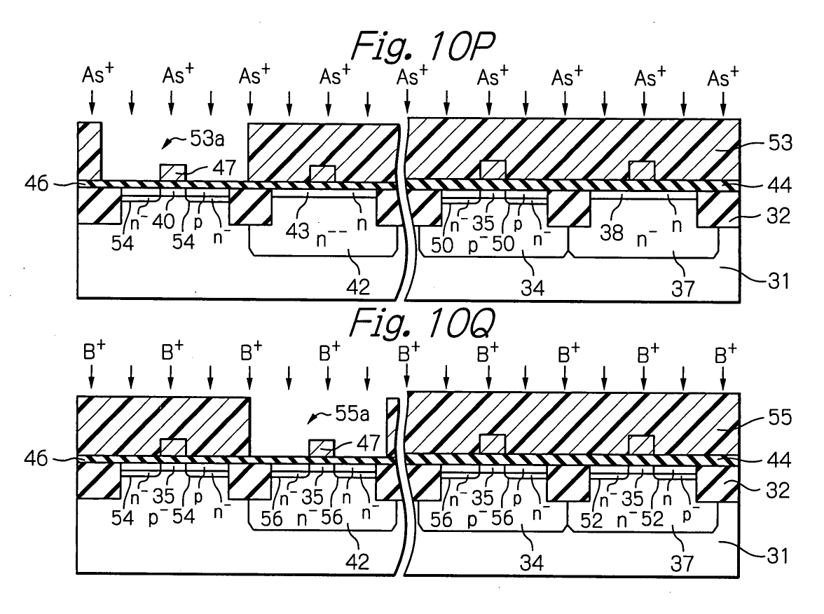

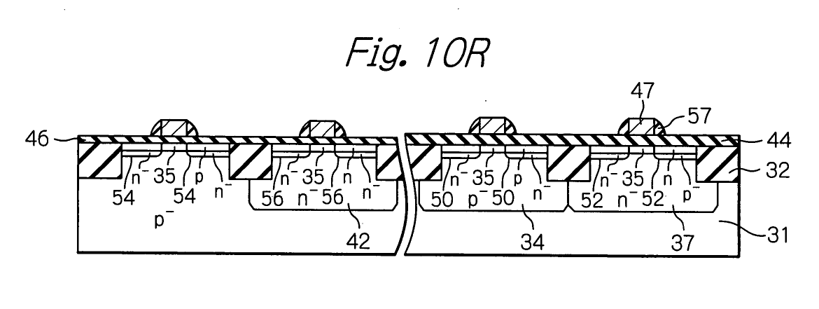

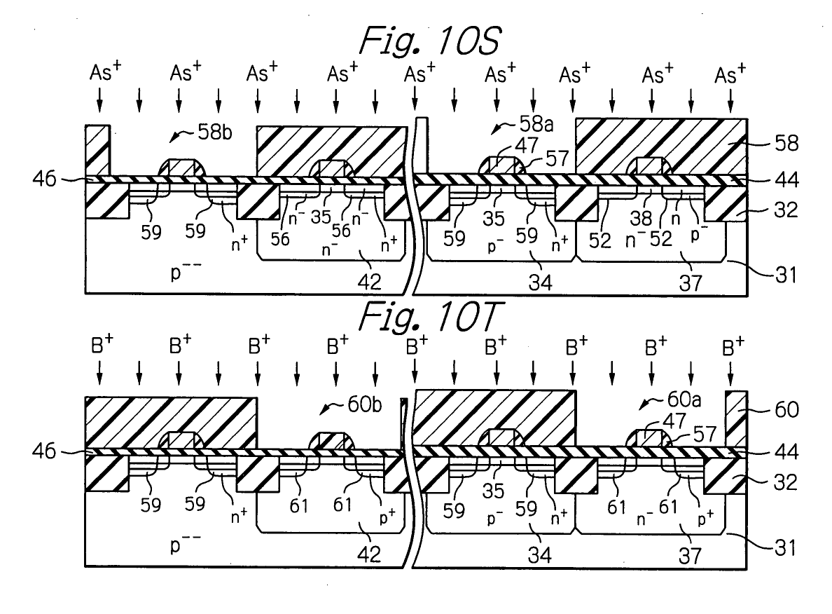

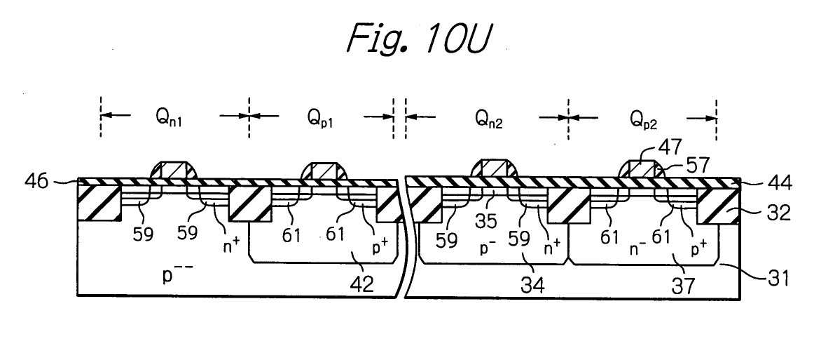

A second embodiment of the method for manufacturing a semiconductor device such as two CMOS circuits will be explained next with reference to FIGS. 10A through 10J. In this case, one CMOS circuit is a low breakdown voltage CMOS circuit formed by one n-channel MOS transistor Qₙ₁ and one p-channel MOS transistor Qₚ₁ powered by 3.3V, and the other CMOS circuit is a high breakdown voltage CMOS circuit formed by one n-channel MOS transistor Qₙ₂ and one p-channel MOS transistor Qₚ₂ powered by 5V.

First, referring to FIG. 10A, an STI layer 32 is formed within a p⁻⁻-type monocrystalline silicon substrate 31 in a similar way to those of FIGS. 6A, 6B, 6C and 6D. As a result, element forming areas (active areas) for the transistors Qₙ₁, Qₚ₁, Qₙ₂ and Qₚ₂ are partitioned from each other.

Next, referring to FIG. 10B, a photoresist pattern layer 33 having an opening 33a corresponding to the n-channel MOS transistor Qₙ₂ is formed on the silicon substrate 31 by a photolithography process. Then, boron ions are implanted at a relatively-high energy into the silicon substrate 31 by using the photoresist pattern layer 33 as a mask, to form a p⁻-type impurity diffusion well 34.

Next, referring to FIG. 10C, boron ions are implanted at a relatively-low energy into the silicon substrate 31 by using the photoresist pattern layer 33 as a mask, to form a p-type impurity diffusion region 35 within the p⁻-type impurity diffusion well 34. Note that the p-type impurity diffusion region 35 is used for adjusting the threshold voltage Vₜₕₙ₂ of the n-channel MOS transistor Qₙ₂. Then, the photoresist pattern layer 33 is removed by an ashing process or the like.

Next, referring to FIG. 10D, a photoresist pattern layer 36 having an opening 36a corresponding to the p-channel MOS transistor Qₚ₂ is formed on the silicon substrate 31 by a photolithography process. Then, arsenic (or phosphorus) ions are implanted at a relatively-high energy into the silicon substrate 31 by using the photoresist pattern layer 36 as a mask, to form an n⁻-type impurity diffusion well 37.

Next, referring to FIG. 10E, arsenic (or phosphorus) ions are implanted at a relatively-low energy into the silicon substrate 31 by using the photoresist pattern layer 36 as a mask, to form an n-type impurity diffusion region 38 within the n⁻-type impurity diffusion well 37. Note that the n-type impurity diffusion region 38 is used for adjusting the threshold voltage Vₜₕₚ₂ of the p-channel MOS transistor Qₚ₂. Then, the photoresist pattern layer 36 is removed by an ashing process or the like.

Next, referring to FIG. 10F, a photoresist pattern layer 39 having an opening 39a corresponding to the n-channel MOS transistor Qₙ₁, openings 39b corresponding to a part of the periphery of the active area of the n-channel MOS transistor Qₙ₂ adjacent to the STI layer 32 that is only beneath a gate electrode 47 which will be formed later, and openings 39c corresponding to a part of the periphery of the active area of the n-channel MOS transistor Qₚ₂ adjacent to the STI layer 32 that is only beneath a gate electrode 47 which will be formed later, is formed on the silicon substrate 31 by a photolithography process. Then, boron ions are implanted at a relatively-low energy into the silicon substrate 31 by using the photoresist pattern layer 39 as a mask, to form a p-type impurity diffusion region 40 within the p⁻⁻-type silicon substrate 31 which in this case serves as a p-type impurity diffusion well. Note that the p-type impurity diffusion region 40 is used for adjusting the threshold voltage Vₜₕₙ₁ of the n-channel MOS transistor Qₙ₁. Simultaneously, p-type impurity diffusion regions (not shown) are formed at the bottom of the openings 39b within the p-type impurity diffusion region 35 and at the bottom of the openings 39c within the n-type impurity diffusion region 38, to compensate for a hump phenomenon and a reverse-hump phenomenon therein. Then, the photoresist pattern layer 39 is removed by an ashing process or the like.

Note that the size of the openings 39b and 39c of FIG. 10F is determined so as to compensate for the hump phenomenon and the reverse-hump phenomenon.

Next, referring to FIG. 10G, a photoresist pattern layer 41 having an opening 41a corresponding to the p-channel MOS transistor Qₚ₁ is formed on the silicon substrate 31 by a photolithography process. Then, arsenic (or phosphorus) ions are implanted at a relatively-high energy into the silicon substrate 31 by using the photoresist pattern layer 41 as a mask, to form an n⁻⁻-type impurity diffusion well 42.

Next, referring to FIG. 10H, arsenic (or phosphorus) ions are implanted at a relatively-low energy into the silicon substrate 31 by using the photoresist pattern layer 41 as a mask, to form an n-type impurity diffusion region 43 within the n⁻⁻-type impurity diffusion well 42. Note that the n-type impurity diffusion region 43 is used for adjusting the threshold voltage Vₜₕₚ₁ of the p-channel MOS transistor Qₚ₁. Then, the photoresist pattern layer 41 is removed by an ashing process or the like.

Next, referring to FIG. 10I, a relatively-thick gate silicon dioxide layer 44 is formed on the entire surface. Note that, if the relatively-thick gate silicon dioxide layer 44 is formed by thermally oxidizing the silicon substrate 31, the relatively-thick gate silicon dioxide layer 44 is not formed on the STI layer 32.

Next, referring to FIG. 10J, a photoresist pattern layer 45 is formed on the gate silicon dioxide layer 44 only on the side of the transistors Qₙ₂ and Qₚ₂. Then, the gate silicon dioxide layer 44 on the side of the transistors Qₙ₁ and Qₚ₁ is selectively etched by using the photoresist pattern layer 44 as an etching mask. Then, the photoresist pattern layer 45 is removed by an ashing process or the like.

Next, referring to FIG. 10K, a relatively-thin gate silicon dioxide layer 46 is formed on the entire surface. In this case, although it is not shown, the relatively-thick gate silicon dioxide layer 44 is also made thicker. Note that, if the relatively-thick gate silicon dioxide layer 46 is formed by thermally oxidizing the silicon substrate 31, the relatively-thin gate silicon dioxide layer 46 is not formed on the STI layer 32.

Thus, the relatively-thick gate silicon dioxide layer 44 is used for the high breakdown voltage transistors Qₙ₂ and Qₚ₂, while the relatively-thin gate silicon dioxide layer 46 is used for the low breakdown voltage transistors Qₙ₁ and Qₚ₁.

Next, referring to FIG. 10L, a polycrystalline silicon layer 47 is deposited on the gate silicon dioxide layers 44 and 46 by a CVD process. Then, a photoresist pattern layer 48 is formed by a photolithography process.

Next, referring to FIG. 10M, the polycrystalline silicon layer 47 is etched by using the photoresist pattern layer 48 as an etching mask to form a gate electrode. Then, the photoresist pattern layer 48 is removed by an ashing process or the like.

Next, referring to FIG. 10N, a photoresist pattern layer 49 having an opening 49a corresponding to the n-channel MOS transistor Qₙ₂ is formed on the gate silicon dioxide layer 44 by a photolithography process. Then, arsenic (or phosphorus) ions are implanted at a relatively-low energy into the silicon substrate 31 by using the photoresist pattern layer 49 as a mask, to form an n⁻-type impurity diffusion regions 50 for an LDD structure. Then, the photoresist pattern layer 49 is removed by an ashing process or the like.

Next, referring to FIG. 100, a photoresist pattern layer 51 having an opening 51a corresponding to the p-channel MOS transistor Qₚ₂ is formed on the gate silicon dioxide layer 44 by a photolithography process. Then, boron ions are implanted at a relatively-low energy into the silicon substrate 31 by using the photoresist pattern layer 51 as a mask, to form a p⁻-type impurity diffusion regions 52 for an LDD structure. Then, the photoresist pattern layer 51 is removed by an ashing process or the like.

Next, referring to FIG. 10P, a photoresist pattern layer 53 having an opening 53a corresponding to the n-channel MOS transistor Qₙ₁ is formed on the gate silicon dioxide layer 46 by a photolithography process. Then, arsenic (or phosphorus) ions are implanted at a relatively-low energy into the silicon substrate 31 by using the photoresist pattern layer 53 as a mask, to form an n⁻-type impurity diffusion regions 54 for an LDD structure. Then, the photoresist pattern layer 53 is removed by an ashing process or the like.

Note that the concentration of the n⁻-type impurity diffusion regions 54 is larger than that of the n⁻-type impurity diffusion regions 50, so that the breakdown voltage of the n-channel MOS transistor Qₙ₁ is smaller than that of the n-channel MOS transistor Qₙ₂.

Next, referring to FIG. 10Q, a photoresist pattern layer 55 having an opening 55a corresponding to the p-channel MOS transistor Qₚ₁ is formed on the gate silicon dioxide layer 46 by a photolithography process. Then, boron ions are implanted at a relatively-low energy into the silicon substrate 31 by using the photoresist pattern layer 55 as a mask, to form a p⁻-type impurity diffusion regions 56 for an LDD structure. Then, the photoresist pattern layer 55 is removed by an ashing process or the like.

Note that the concentration of the n⁻-type impurity diffusion regions 56 is larger than that of the n⁻-type impurity diffusion regions 52, so that the breakdown voltage of the n-channel MOS transistor Qₚ₁ is smaller than that of the n-channel MOS transistor Qₚ₂.

Next, referring to FIG. 10R, a silicon dioxide layer is deposited on the entire surface by a CVD process, and the silicon dioxide layer is etched back by an anisotropic etching process. As a result, a sidewall silicon dioxide layer 57 is formed on the sidewalls of the gate electrodes 47.

Next, referring to FIG. 10S, a photoresist pattern layer 58 having openings 58a and 58b corresponding to the n-channel MOS transistors Qₙ₂ and Qₙ₁ formed on the gate silicon dioxide layers 44 and 46 by a photolithography process. Then, arsenic (or phosphorus) ions are implanted at a relatively-high energy into the silicon substrate 31 by using the photoresist pattern layer 58 as a mask, to form n⁺-type impurity diffusion regions 59. Then, the photoresist pattern layer 58 is removed by an ashing process or the like.

Next, referring to FIG. 10T, a photoresist pattern layer 60 having openings 60a and 60b corresponding to the p-channel MOS transistors Qₚ₂ and Qₚ₁ is formed on the gate silicon dioxide layers 44 and 46 by a photolithography process. Then, boron ions are implanted at a relatively-high energy into the silicon substrate 31 by using the photoresist pattern layer 60 as a mask, to form a p⁺-type impurity diffusion regions 61. Then, the photoresist pattern layer 60 is removed by an ashing process or the like.

Thus, a CMOS semiconductor device having two kinds of breakdown voltages is obtained as illustrated in FIG. 10U. Note that the gate silicon dioxide layers 44 and 46 on the impurity diffusion regions 59 and 61 are removed immediately before silicide layers (not shown) are formed at a post stage. However, the gate silicon dioxide layers 44 and 46 on the impurity diffusion regions 50, 52, 54, 56, 59 and 61 can be removed in self-alignment with the gate electrodes 47 immediately after the latter are formed.

In the above-described second embodiment, the formation of the p-type impurity diffusion regions (not shown) under the openings 39b and 39c of FIG. 10F is carried out simultaneously with the formation of the p-type impurity diffusion region 40 under the opening 39a of FIG. 10F, so that additional processes for the former p-type impurity diffusion regions are unnecessary, which would not increase the manufacturing steps.

Also, in the above-described second embodiment, the p-type impurity diffusion regions under the openings 39b and 39c are at a part of active areas adjacent to the STI layer 32 that is only beneath the gate electrodes; however, even if these p-type impurity diffusion regions are formed at the entire periphery of the active areas as in the prior art, additional processes therefor are unnecessary, which would not increase the manufacturing steps.

In the above-described embodiments, a thick element isolation layer is formed by an STI layer; however, this thick element isolation layer can be formed by a LOCOS layer.

As explained hereinabove, according to the present invention, the breakdown voltage characteristics can be improved while the hump phenomenon or the reverse-hump phenomenon can be compensated for so that the improvement of the sub threshold characteristics is maintained.

1-17. (canceled)

18. A method for manufacturing a MOS transistor, comprising:
forming a MOS transistor isolation layer within a semiconductor substrate to surround an area for forming said MOS transistor in said semiconductor substrate;
introducing first impurities into said area of said semiconductor substrate to adjust a threshold voltage of said MOS transistor; and
introducing second impurities into only a part of a periphery of said area adjacent to said MOS transistor isolation layer above which a gate electrode of said MOS transistor will be formed.

19. The method as set forth in claim 18, wherein said first and second impurities are both boron atoms.

20. The method as set forth in claim 18, wherein said first impurities are arsenic atoms and said second impurities are boron atoms.

21. The method as set forth in claim 18, wherein said first impurities are phosphorus atoms and said second impurities are boron atoms.

22. The method as set forth in claim 18, wherein said semiconductor substrate comprises a silicon substrate, and said MOS transistor isolation layer comprises a silicon dioxide layer.

23. The method as set forth in claim 22, wherein said silicon dioxide layer comprises a shallow trench isolation (STI) layer.

24. The method as set forth in claim 22, wherein said silicon dioxide layer comprises a local oxidation of silicon (LOCOS) layer.

25. A method for manufacturing a semiconductor device including first and second MOS transistors, comprising:
forming MOS transistor isolation layers within a semiconductor substrate to surround first and second areas for forming said first and second MOS transistors, respectively, in said semiconductor substrate;
introducing first impurities into said first area of said semiconductor substrate to adjust a first threshold voltage of said first MOS transistor;
introducing second impurities into said second area of said semiconductor substrate to adjust a second threshold voltage of said second MOS transistor; and
introducing third impurities into only a part of a periphery of said first area adjacent to said first MOS transistor isolation layer above which a gate electrode of said first MOS transistor will be formed,
said second and third impurities being the same impurities.

26. The method as set forth in claim 25, wherein introduction of said second and third impurities is simultaneously carried out.

27. The method as set forth in claim 25, wherein said first, second and third impurities are all boron atoms.

28. The method as set forth in claim 25, wherein said first impurities are arsenic atoms and said second and third impurities are boron atoms.

29. The method as set forth in claim 25, wherein said first impurities are phosphorus atoms and said second and third impurities are boron atoms.

30. The method as set forth in claim 25, wherein the breakdown voltage of said first MOS transistor is higher than that of said second MOS transistor.

31. The method as set forth in claim 25, wherein said semiconductor substrate comprises a silicon substrate, and said MOS transistor isolation layer comprises a silicon dioxide layer.

32. The method as set forth in claim 31, wherein said silicon dioxide layer comprises a shallow trench isolation (STI) layer.

33. The method as set forth in claim 31, wherein said silicon dioxide layer comprises a local oxidation of silicon (LOCOS) layer.

34. A method for manufacturing a semiconductor device including first and second MOS transistors, comprising:
forming MOS transistor isolation layers within a semiconductor substrate to surround first and second areas for forming said first and second MOS transistors, respectively, in said semiconductor substrate;
introducing first impurities into said first area of said semiconductor substrate to adjust a first threshold voltage of said first MOS transistor;
introducing second impurities into said second area of said semiconductor substrate to adjust a second threshold voltage of said second MOS transistor; and
introducing third impurities into the entire periphery of said first area adjacent to said first MOS transistor isolation layer above which a gate electrode of said first MOS transistor will be formed,
said second and third impurities being the same impurities, so that introduction of said second and third impurities is simultaneously carried out.
